(19) United States
(12) Patent Application Publication
(10) Pub. No.: US 2021/0126308 A1
(43) Pub. Date: Apr. 29, 2021

(54) ELECTRONIC DEVICE(S)

(71) Applicant: HEWLETT-PACKARD DEVELOPMENT COMPANY, L.P., SPRING, TX (US)

(72) Inventors: KUAN-TING WU, TAIPEI CITY (TW); CHENG-FENG LIAO, TAIPEI CITY (TW); CHI HAO CHANG, TAIPEI CITY (TW)

(21) Appl. No.: 16/605,923

(22) PCT Filed: Jun. 20, 2017
(86) PCT No.: PCT/US2017/038230

§ 371 Date: Oct. 17, 2019

(51) Int. Cl. H01M 50/121

(52) U.S. Cl. CPC H01M 50/121

(57) ABSTRACT

Electronic devices comprising a polymeric material at least partially enclosed by an anodized metal are disclosed herein. The polymeric material can comprise a polymer composite, a carbon fiber composite, or mixtures thereof. The anodized metal can be selected from the group consisting of anodized aluminum, anodized aluminum alloy, anodized titanium, anodized titanium alloy, anodized zinc, anodized zinc alloy, anodized magnesium, anodized magnesium alloy, anodized niobium, anodized niobium alloy, anodized zirconium, anodized zirconium alloy, anodized hafnium, anodized hafnium alloy, anodized tantalum, anodized tantalum alloy, and combinations thereof.

### BACKGROUND

Electronic devices such as desktop computers, laptop computers, mobile phones, handheld devices, printing devices, and other electronic devices tend to use polymeric composite materials to form the external and internal frames. These materials tend to have similar appearances and mechanical strengths.

### BRIEF DESCRIPTION OF THE DRAWINGS

Features of examples of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIG. 1 is a perspective view of an electronic device substrate enclosed by an anodized metal according to an example;

FIG. 1A is a cross-sectional view of the electronic device substrate enclosed by the anodized metal shown in FIG. 1;

FIG. 2 is a perspective view of an electronic device substrate enclosed by an anodized metal according to an example;

FIG. 2A is a cross-sectional view of the electronic device substrate enclosed by the anodized metal shown in FIG. 2;

FIG. 3 is a perspective view of an electronic device substrate enclosed by an anodized metal according to an example;

FIG. 3A is a cross-sectional view of the electronic device substrate enclosed by the anodized metal shown in FIG. 3;

FIG. 4 is a perspective view of an electronic device substrate enclosed by an anodized metal according to an example;

FIG. 4A is a cross-sectional view of the electronic device substrate enclosed by the anodized metal shown in FIG. 4;

FIG. 5 is a perspective view of an electronic device substrate enclosed by an anodized metal according to an example;

FIG. 5A is a cross-sectional view of the electronic device substrate enclosed by the anodized metal shown in FIG. 5;

FIG. 6 is a perspective view of an electronic device substrate enclosed by an anodized metal according to an example;

FIG. 6A is a cross-sectional view of the electronic device substrate enclosed by the anodized metal shown in FIG. 6;

FIG. 7 is a perspective view of an electronic device substrate enclosed by an anodized metal according to an example;

FIG. 7A is a cross-sectional view of the electronic device substrate enclosed by the anodized metal shown in FIG. 7;

FIG. 8 is a perspective view of an electronic device substrate enclosed by an anodized metal according to an example;

FIG. 8A is a cross-sectional view of the electronic device substrate enclosed by the anodized metal shown in FIG. 8;

FIG. 9 is a perspective view of an electronic device substrate enclosed by an anodized metal according to an example;

FIG. 9A is a cross-sectional view of the electronic device substrate enclosed by the anodized metal shown in FIG. 9;

FIG. 10 is a flowchart fora method of making an enclosed substrate according to an example; and

FIG. 11 is a flowchart for a method of making an enclosed substrate according to another example.

### DETAILED DESCRIPTION

Most electronic device(s) can broadly include two portions: an electronics portion, which can serve the functional use of the electronic device and an external frame portion, which can offer physical protection and/or an aesthetically pleasing appearance to the electronics portion housed within the external frame portion. In order to offer enhanced protection, the external frame can physically encapsulate the electronics. The electronics portion can include but is not limited to microprocessors, memory devices, and/or storage devices.

The external frame portion can, in some examples, achieve a less aesthetically pleasing appearance in addition to offering insufficient mechanical strength to adequately protect the electronics enclosed within.

Accordingly, a need exists for an electronics case (i.e., external frame portion) which is not only aesthetically pleasing but could also improve the structural integrity and durability of an electronic device without increasing its weight in an appreciable amount.

In some examples, described herein is an electronic device comprising: a polymeric material at least partially enclosed by an anodized metal, wherein the polymeric material comprises a polymer composite, a carbon fiber composite, or mixtures thereof, wherein the polymer composite comprises silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, wherein the carbon fiber composite comprises (i) carbon fibers, and (ii) silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, and wherein the anodized metal is selected from the group consisting of anodized aluminum, anodized aluminum alloy, anodized titanium, anodized titanium alloy, anodized zinc, anodized zinc alloy, anodized magnesium, anodized magnesium alloy, anodized niobium, anodized niobium alloy, anodized zirconium, anodized zirconium alloy, anodized hafnium, anodized hafnium alloy, anodized tantalum, anodized tantalum alloy, and combinations thereof.

The electronic device is not limited to and can include desktop computers, laptop computers, mobile phones, handheld devices, and printing devices.

In some examples, the anodized metal can be integrally attached to the polymeric material.

The polymeric material can, in some examples, form a substrate. The substrate can include any internal component or an electronic device—e.g., CPU board or display screen. In some examples, the substrate can be completely enclosed by the anodized metal. As used herein “substrate” is used interchangeably with “polymeric material.”

In some examples, the substrate can be at least partially enclosed by the anodized metal. In some examples, the substrate can be enclosed by the anodized metal on a bottom surface of the substrate. In some examples, the substrate can be enclosed by the anodized metal on a top surface of the substrate. In some examples, the substrate is enclosed by the anodized metal on at least one side edge of the substrate. In some examples, a combination of the foregoing examples can be used.

In some examples, the anodized metal can be present in an amount of from about 1 wt % to about 40 wt % based on the total weight of the substrate, or from about 5 wt % to about 35 wt % based on the total weight of the substrate, or from about 10 wt % to about 30 wt % based on the total weight of the substrate, or in an amount less than about 50 wt % based on the total weight of the substrate, or in an amount less than about 45 wt % based on the total weight of the substrate, or in an amount less than about 40 wt % based on the total weight of the substrate, or in an amount less than about 35 wt % based on the total weight of the substrate, or in an amount less than about 30 wt % based on the total weight of the substrate, or in an amount less than about 25 wt % based on the total weight of the substrate, or in an amount less than about 20 wt % based on the total weight of the substrate, or in an amount of at least about 1 wt % based on the total weight of the substrate, or in an amount of at least about 5 wt % based on the total weight of the substrate, or in an amount of at least about 10 wt % based on the total weight of the substrate, or in an amount of at least about 15 wt % based on the total weight of the substrate, or in an amount of at least about 20 wt % based on the total weight of the substrate, or in an amount of at least about 25 wt % based on the total weight of the substrate, or in an amount of at least about 30 wt % based on the total weight of the substrate.

In some examples, the anodized metal can be coated with at least one paint layer. The paint layer is interchangeably referred to herein as “color coating.”

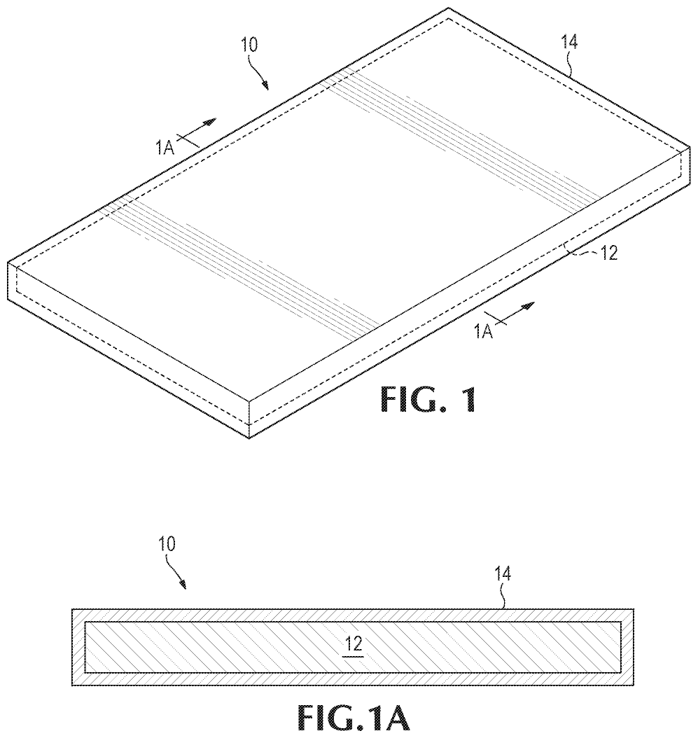

FIG. 1 is a perspective view of an electronic device substrate enclosed by an anodized metal according to an example. In FIG. 1, an enclosed electronic device substrate 10 includes a substrate 12, which is fully enclosed by an anodized metal 14. In this example, the substrate 12 is enclosed by the anodized metal 14 on a top surface of the substrate 12, a bottom surface of the substrate 12, and all edges of the substrate 12.

FIG. 1A is a cross-sectional view taken along line 1A of the enclosed electronic device substrate 10 shown in FIG. 1. In FIG. 1A, the substrate 12 is shown as fully enclosed by the anodized metal 14 on the top surface of the substrate 12, the bottom surface of the substrate 12, and all the edges of the substrate 12.

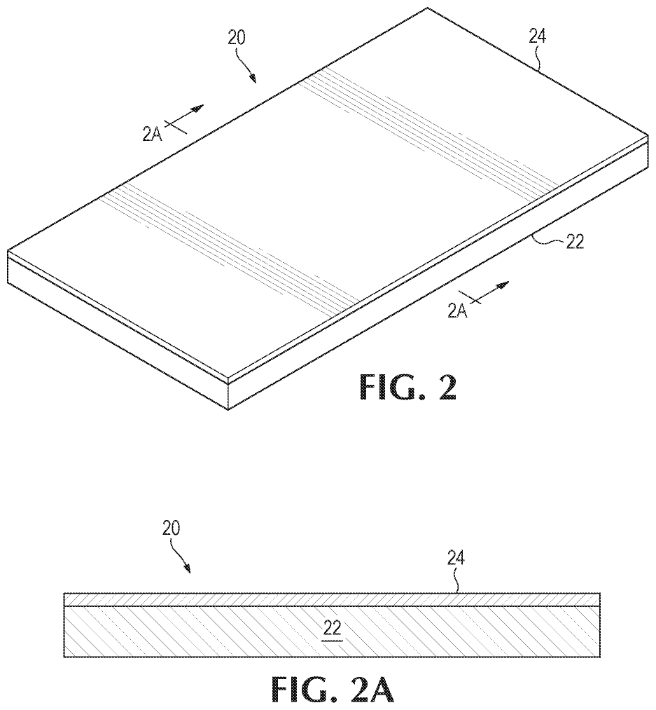

FIG. 2 is a perspective view of an electronic device substrate enclosed by an anodized metal according to an example. In FIG. 2, an enclosed electronic device substrate 20 includes a substrate 22, which is partially enclosed by an anodized metal 24. In this example, the substrate 22 is enclosed by the anodized metal 24 on a top surface of the substrate 22.

FIG. 2A is a cross-sectional view taken along line 2A of the enclosed electronic device substrate 20 shown in FIG. 2. In FIG. 2A, the substrate 22 is shown as partially enclosed by the anodized metal 24 on the top surface of the substrate 22.

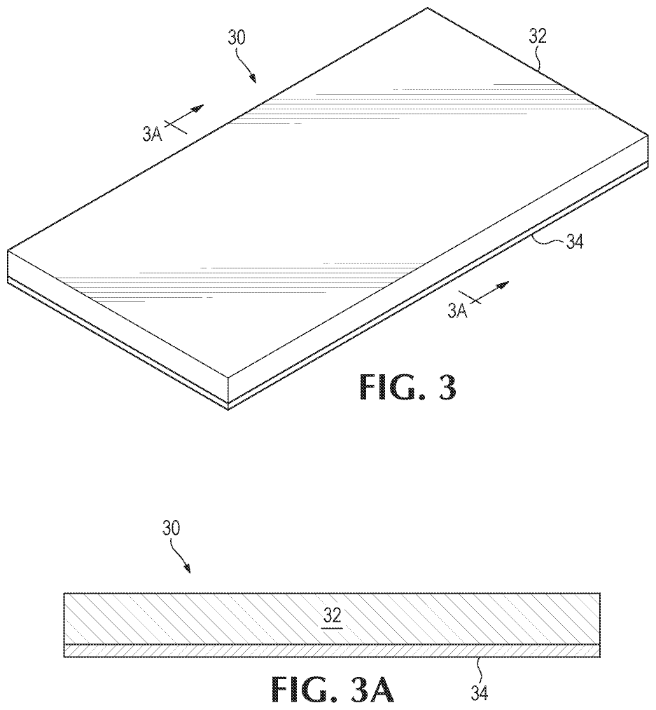

FIG. 3 is a perspective view of an electronic device substrate enclosed by an anodized metal according to an example. In FIG. 3, an enclosed electronic device substrate 30 includes a substrate 32, which is partially enclosed by an anodized metal 34. In this example, the substrate 32 is enclosed by the anodized metal 34 on a bottom surface of the substrate 32.

FIG. 3A is a cross-sectional view taken along line 3A of the enclosed electronic device substrate 30 shown in FIG. 3. In FIG. 3A, the substrate 32 is shown as partially enclosed by the anodized metal 34 on the bottom surface of the substrate 32.

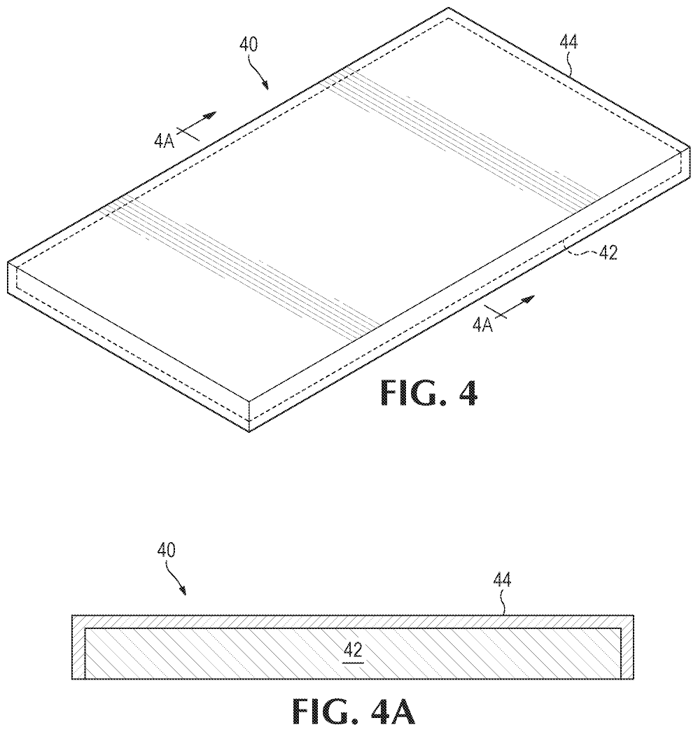

FIG. 4 is a perspective view of an electronic device substrate enclosed by an anodized metal according to an example. In FIG. 4, an enclosed electronic device substrate 40 includes a substrate 42, which is partially enclosed by an anodized metal 44. In this example, the substrate 42 is enclosed by the anodized metal 44 on a top surface of the substrate 42 and all edges of the substrate 42.

FIG. 4A is a cross-sectional view taken along line 4A of the enclosed electronic device substrate 40 shown in FIG. 4. In FIG. 4A, the substrate 42 is shown as partially enclosed by the anodized metal 44 on the top surface of the substrate 42 and all the edges of the substrate 42.

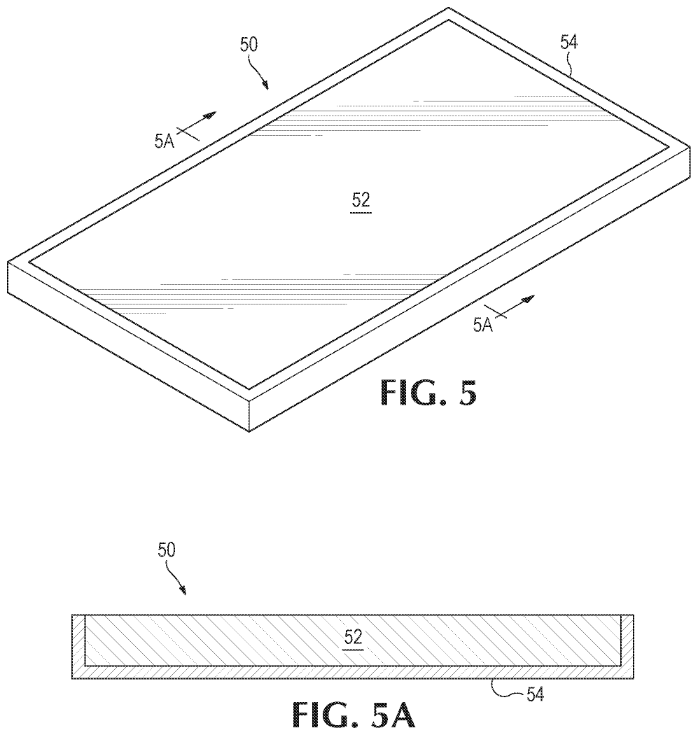

FIG. 5 is a perspective view of an electronic device substrate enclosed by an anodized metal according to an example. In FIG. 5, an enclosed electronic device substrate 50 includes a substrate 52, which is partially enclosed by an anodized metal 54. In this example, the substrate 52 is enclosed by the anodized metal 54 on a bottom surface of the substrate 52 and all edges of the substrate 52.

FIG. 5A is a cross-sectional view taken along line 5A of the enclosed electronic device substrate 50 shown in FIG. 5. In FIG. 5A, the substrate 52 is shown as partially enclosed by the anodized metal 54 on the bottom surface of the substrate 52 and all the edges of the substrate 52.

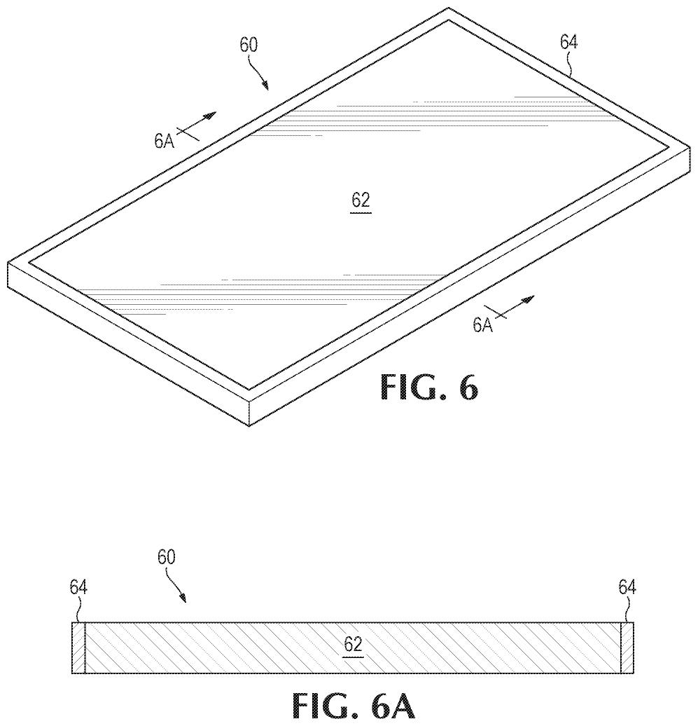

FIG. 6 is a perspective view of an electronic device substrate enclosed by an anodized metal according to an example. In FIG. 6, an enclosed electronic device substrate 60 includes a substrate 62, which is partially enclosed by an anodized metal 64. In this example, the substrate 62 is enclosed by the anodized metal 64 on all edges of the substrate 62.

FIG. 6A is a cross-sectional view taken along line 6A of the enclosed electronic device substrate 60 shown in FIG. 6. In FIG. 6A, the substrate 62 is shown as partially enclosed by the anodized metal 64 on all the edges of the substrate 62.

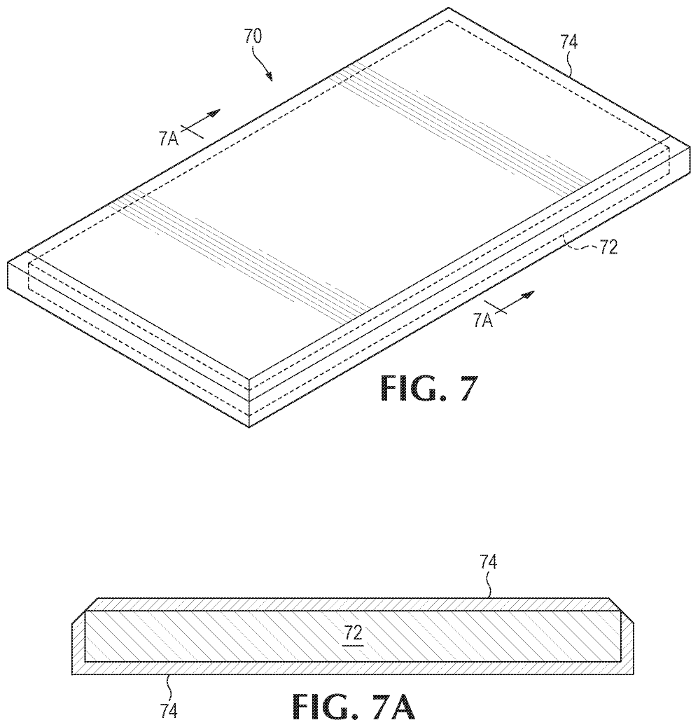

FIG. 7 is a perspective view of an electronic device substrate enclosed by an anodized metal according to an example. In FIG. 7, an enclosed electronic device substrate 70 includes a substrate 72, which is fully enclosed by an anodized metal 74. In this example, the substrate 72 is enclosed by the anodized metal 74 on a top surface of the substrate 72, a bottom surface of the substrate 72, and all edges of the substrate 72. The edges of the substrate 72 are mechanically shaped to form beveled edges.

FIG. 7A is a cross-sectional view taken along line 7A of the enclosed electronic device substrate 70 shown in FIG. 7. In FIG. 7A, the substrate 72 is shown as fully enclosed by the anodized metal 74 on the top surface of the substrate 72, the bottom surface of the substrate 72, and all the edges of the substrate 72 with the edges of the substrate 72 mechanically shaped to form beveled edges.

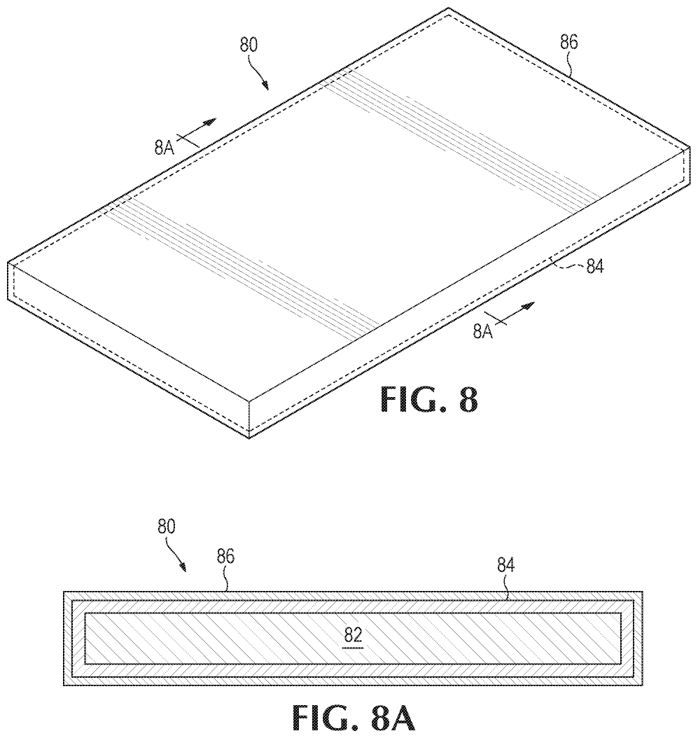

FIG. 8 is a perspective view of an electronic device substrate enclosed by an anodized metal according to an example. In FIG. 8, an enclosed electronic device substrate 80 includes a substrate 82, which is fully enclosed by an anodized metal 84. In this example, the substrate 82 is enclosed by the anodized metal 84 on a top surface of the substrate 82, a bottom surface of the substrate 82, and all edges of the substrate 82. In this example, a color coating 86 is layered on top of the anodized metal 84.

FIG. 8A is a cross-sectional view taken along line 8A of the enclosed electronic device substrate 80 shown in FIG. 8. In FIG. 8A, the substrate 82 is shown as fully enclosed by the anodized metal 84 on the top surface of the substrate 82, the bottom surface of the substrate 82, and all the edges of the substrate 82. The color coating 86 is layered on top of the anodized metal 84.

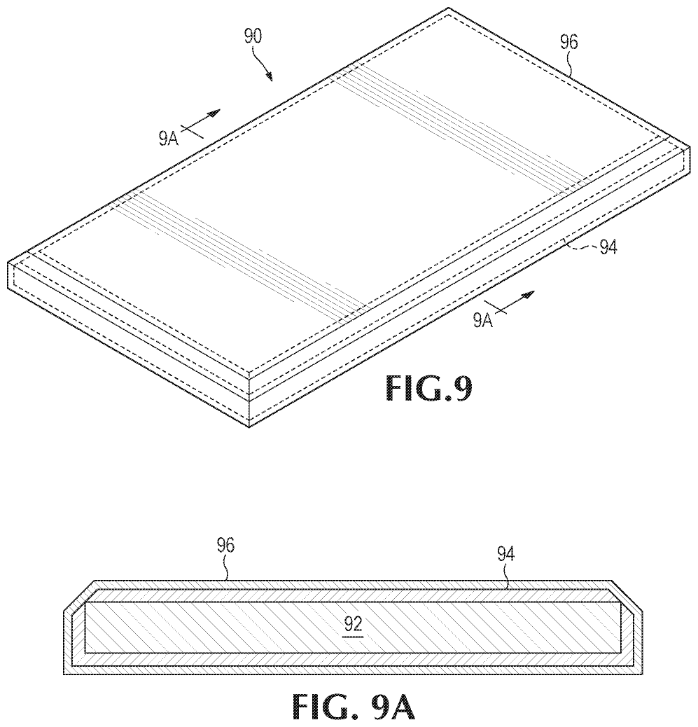

FIG. 9 is a perspective view of an electronic device substrate enclosed by an anodized metal according to an example. In FIG. 9, an enclosed electronic device substrate 90 includes a substrate 92, which is fully enclosed by an anodized metal 94. In this example, the substrate 92 is enclosed by the anodized metal 94 on a top surface of the substrate 92, a bottom surface of the substrate 92, and all edges of the substrate 92 with the edges of the substrate 92 mechanically shaped to form beveled edges. In this example, a color coating 96 is layered on top of the anodized metal 94.

FIG. 9A is a cross-sectional view taken along line 9A of the enclosed electronic device substrate 90 shown in FIG. 9. In FIG. 9A, the substrate 92 is shown as fully enclosed by the anodized metal 94 on the top surface of the substrate 92, the bottom surface of the substrate 92, and all the edges of the substrate 92 with the edges of the substrate 92 mechanically shaped to form beveled edges. The color coating 96 is layered on top of the anodized metal 94.

“Completely enclosed,” as used herein, refers to the substrate enclosed by the anodized metal on all surfaces of the substrate. It will be understood, however, that any port accesses or other openings can be allowed in the anodized metal for connectivity and/or functioning.

“Substrate(s) enclosed by anodized metal(s),” as used herein refers to electronic device substrates at least partially enclosed by at least one anodized metal. It will be understood, however, that any port accesses or other openings can be allowed in the anodized metal for connectivity and/or functioning.

“Partially enclosed,” as used herein, refers to the substrate enclosed by the anodized metal on at least one surface of the substrate but not all surfaces of the substrate. It will be understood that a substrate, as used herein, can have more than four sides. It will be understood, however, that any port accesses or other openings can be allowed in the anodized metal for connectivity and/or functioning.

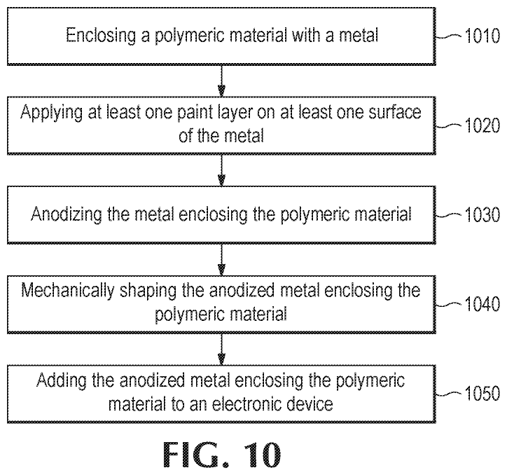

In some examples, a method of making an enclosed substrate is disclosed. The method, as shown in FIG. 10, can comprise: (A) enclosing a polymeric material with a metal 1010, wherein the polymeric material comprises a polymer composite, a carbon fiber composite, or mixtures thereof, wherein the polymer composite comprises silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, wherein the carbon fiber composite comprises (i) carbon fibers, and (ii) silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, and wherein the metal is selected from the group consisting of aluminum, aluminum alloy, titanium, titanium alloy, zinc, zinc alloy, magnesium, magnesium alloy, niobium, niobium alloy, zirconium, zirconium alloy, hafnium, hafnium alloy, tantalum, tantalum alloy, and combinations thereof; (B) anodizing the metal enclosing the polymeric material 1030; and (C) adding the anodized metal enclosing the polymeric material to an electronic device 1050.

The method can further comprise: (A-1) applying at least one paint layer on at least one surface of the metal 1020. In some examples, the applying of the color coating or paint layer can occur any time after at least partially enclosing a substrate and before adding the at least partially enclosed substrate to an electronic device.

The method can further comprise: (B-1) mechanically shaping the anodized metal enclosing the polymeric material 1040. In some examples, the mechanical shaping can occur any time after at least partially enclosing a substrate and before adding the at least partially enclosed substrate to an electronic device.

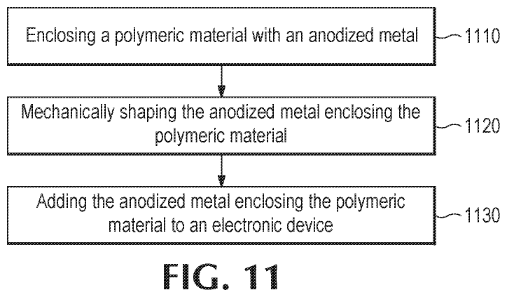

In some examples, disclosed herein is another method of making an enclosed substrate. The method, as shown in FIG. 11, can comprise: (A) enclosing a polymeric material with an anodized metal 1110, wherein the polymeric material comprises a polymer composite, a carbon fiber composite, or mixtures thereof, wherein the polymer composite comprises silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, wherein the carbon fiber composite comprises (i) carbon fibers, and (ii) silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, and wherein the anodized metal is selected from the group consisting of anodized aluminum, anodized aluminum alloy, anodized titanium, anodized titanium alloy, anodized zinc, anodized zinc alloy, anodized magnesium, anodized magnesium alloy, anodized niobium, anodized niobium alloy, anodized zirconium, anodized zirconium alloy, anodized hafnium, anodized hafnium alloy, anodized tantalum, anodized tantalum alloy, and combinations thereof; and (B) adding the anodized metal enclosing the polymeric material to an electronic device 1130. The method can further comprise: (A-2) mechanically shaping the anodized metal enclosing the polymeric material 1120. In some examples, the mechanical shaping can occur any time after at least partially enclosing a substrate and before adding the at least partially enclosed substrate to an electronic device.

In some examples, an adhesive can be used to aid enclosing the substrate with the metal or the anodized metal. The adhesive can be a commonly used adhesive comprising an epoxy or a silane.

In examples where the substrate is at least partially enclosed by a metal, the metal can be anodized any time after at least partially enclosing a substrate and before adding to an electronic device.

In some examples, the substrate can be at least partially enclosed by the anodized metal by injection molding. In this process, a substrate may be set inside a mold and a metal may then be injected into the mold. The substrate at least partially enclosed by the metal once removed from the injection molding line, can then be anodized some time before adding to an electronic device.

Alternatively, another method that may be used involves pre-molding at least a part of a metal by die casting or another molding method, enclosing the substrate in the pre-molded metal, and compression-molding at, for example, between about 120° C. and 170° C. for a period of about one to about five minutes to attach the pre-molded metal around the substrate. The substrate at least partially enclosed by the metal can then be anodized some time before adding to an electronic device.

In another method, a metal may be at least partially cast around the substrate. The metal can be cured in a closed mold. The casting process may be performed under nitrogen. A portion of the metal may be formed in a mold over the substrate, then another portion of the metal can be assembled to the first portion and cured to form a finished enclosure. The surface of the substrate may be surface-treated before the metal is formed over it to increase the adhesion between the substrate and the enclosure. The substrate at least partially enclosed by the metal can then be anodized some time before adding to an electronic device.

In another method, an anodized metal may be at least partially mechanically shaped around the substrate using an automated process or a batch process by machine or hand to at least partially enclose the substrate.

In some examples, a color coating, which is sometimes referred herein as a “paint layer,” can be applied on the metal at least partially enclosing a substrate. The color coated metal, which at least partially encloses the substrate, can then be anodized some time before adding the at least partially enclosed substrate to an electronic device.

In some examples, a color coating, which is sometimes referred herein as a “paint layer,” can be applied on the anodized metal at least partially enclosing a substrate.

In some examples, the color coating or paint layer can be applied to the metal or the anodized metal by using any known technique including but not limited to spraying, dipping, wiping, or brushing with a colored composition such as a paint. In some examples, the color coating or paint layer can be applied to the metal or the anodized metal by spray painting, powder coating, or electroplating.

In some examples, the anodizing of the metal can be carried out using known anodizing techniques including but not limited to electrochemically forming a corresponding metal oxide coating. The electrochemical forming of the metal oxide is referred to as anodizing. These metal oxides can enhance the hardness, durability, and weather resistance of the base metal.

In some examples, the metal or the anodized metal can be mechanically shaped by machine or by hand. Mechanically shaping the metal or the anodized metal can improve the aesthetic appearance and use/handling of the mechanically shaped metal or anodized metal. In some examples, mechanical shaping can include forming beveled edges in the metal or anodized metal which at least partially encloses the substrate. The mechanical shaping can include other effects including but not limited to forming various shapes, die-cutting for design or function, or forming different surfaces (e.g., smooth or rough) for aesthetic or functional reasons.

In some examples, the anodized metal enclosing the substrate can be added to an electronic device using known techniques including but not limited to assembling and/or soldering.

In some examples, a thickness of the anodized metal at least partially enclosing the substrate can be from about 0.05 mm to about 10 mm, or a thickness of the anodized metal on the substrate can be from about 0.1 mm to about 1 mm, or a thickness of the anodized metal on the substrate can be from about 0.5 mm to about 1 mm, or a thickness of the anodized metal on the substrate can be less than about 20 mm, or a thickness of the anodized metal on the substrate can be less than about 15 mm, or a thickness of the anodized metal on the substrate can be less than about 10 mm, or a thickness of the anodized metal on the substrate can be less than about 5 mm, or a thickness of the anodized metal on the substrate can be between about 10 mm and 30 mm, or a thickness of the anodized metal on the substrate can be between about 10 mm and 25 mm.

In some examples, the anodized metal can act as a barrier between the enclosed substrate and a point of contact (e.g., ground or an object falling on the electronic device) during a damaging event such as dropping or falling of the electronic device comprising the substrate at least partially enclosed by the anodized metal. In some examples, the anodized metal can absorb impact energy without causing glass or ceramic substrate breakage and metal or composite substrate deformation or damage.

Materials for a substrate and an anodized metal, both of which are described hereinabove, can be purchased from manufacturers or can be prepared using known techniques/methods.

Unless otherwise stated, any feature described hereinabove can be combined with any example or any other feature described herein.

As used herein, “(s)” at the end of some terms indicates that those terms/phrases may be singular in some examples or plural in some examples. It is to be understood that the terms without “(s)” may be also be used singularly or plurally in many examples.

In describing and claiming the examples disclosed herein, the singular forms “a,” “an,” and “the” include plural referents unless the context clearly dictates otherwise.

It is to be understood that concentrations, amounts, and other numerical data may be expressed or presented herein in range formats. It is to be understood that such range formats are used merely for convenience and brevity and thus should be interpreted flexibly to include not just the numerical values explicitly recited as the end points of the range, but also to include all the individual numerical values or sub-ranges encompassed within that range as if each numerical value and sub-range is explicitly recited. As an illustration, a numerical range of “about 1 wt % to about 5 wt %” should be interpreted to include not just the explicitly recited values of about 1 wt % to about 5 wt %, but also include individual values and subranges within the indicated range. Thus, included in this numerical range are individual values such as 2, 3.5, and 4 and sub-ranges such as from 1-3, from 2-4, and from 3-5, etc. This same applies to ranges reciting a single numerical value.

Reference throughout the specification to “one example,” “some examples,” “another example,” “an example,” and so forth, means that a particular element (e.g., feature, structure, and/or characteristic) described in connection with the example is included in at least one example described herein, and may or may not be present in other examples. In addition, it is to be understood that the described elements for any example may be combined in any suitable manner in the various examples unless the context clearly dictates otherwise.

Unless otherwise stated, references herein to “wt %” of a component are to the weight of that component as a percentage of the whole composition comprising that component. For example, references herein to “wt %” of, for example, a solid material such as polyurethane(s) or colorant(s) dispersed in a liquid composition are to the weight percentage of those solids in the composition, and not to the amount of that solid as a percentage of the total non-volatile solids of the composition.

If a standard test is mentioned herein, unless otherwise stated, the version of the test to be referred to is the most recent at the time of filing this patent application.

All amounts disclosed herein and in the examples below are in wt % unless indicated otherwise.

While several examples have been described in detail, it is to be understood that the disclosed examples may be modified. Therefore, the foregoing description is to be considered non-limiting.

What is claimed is:

1. An electronic device comprising:
a polymeric material at least partially enclosed by an anodized metal,
wherein the polymeric material comprises a polymer composite, a carbon fiber composite, or mixtures thereof,
wherein the polymer composite comprises silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof,
wherein the carbon fiber composite comprises (i) carbon fibers, and (ii) silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, and
wherein the anodized metal is selected from the group consisting of anodized aluminum, anodized aluminum alloy, anodized titanium, anodized titanium alloy, anodized zinc, anodized zinc alloy, anodized magnesium, anodized magnesium alloy, anodized niobium, anodized niobium alloy, anodized zirconium, anodized zirconium alloy, anodized hafnium, anodized hafnium alloy, anodized tantalum, anodized tantalum alloy, and combinations thereof.

2. The electronic device of claim 1, wherein the anodized metal is integrally attached to the polymeric material.

3. The electronic device of claim 1, wherein the polymeric material forms a substrate.

4. The electronic device of claim 3, wherein the substrate is completely enclosed by the anodized metal.

5. The electronic device of claim 3, wherein the substrate is at least partially enclosed by the anodized metal.

6. The electronic device of claim 5, wherein the anodized metal is present in an amount of from about 1 wt % to about 40 wt % based on the total weight of the substrate.

7. The electronic device of claim 5, wherein the substrate is enclosed by the anodized metal on a bottom surface of the substrate.

8. The electronic device of claim 5, wherein the substrate is enclosed by the anodized metal on a top surface of the substrate.

9. The electronic device of claim 5, wherein the substrate is enclosed by the anodized metal on at least one side edge of the substrate.

10. The electronic device of claim 5, wherein the anodized metal is coated with at least one paint layer.

11. A method of making an enclosed substrate, the method comprising:
(A) enclosing a polymeric material with a metal,
wherein the polymeric material comprises a polymer composite, a carbon fiber composite, or mixtures thereof,
wherein the polymer composite comprises silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof,
wherein the carbon fiber composite comprises (i) carbon fibers, and (ii) silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, and
wherein the metal is selected from the group consisting of aluminum, aluminum alloy, titanium, titanium alloy, zinc, zinc alloy, magnesium, magnesium alloy, niobium, niobium alloy, zirconium, zirconium alloy, hafnium, hafnium alloy, tantalum, tantalum alloy, and combinations thereof;
(B) anodizing the metal enclosing the polymeric material; and
(C) adding the anodized metal enclosing the polymeric material to an electronic device.

12. The method of claim 11 further comprising:
(B-1) mechanically shaping the anodized metal enclosing the polymeric material.

13. The method of claim 11 further comprising:
(A-1) applying at least one paint layer on at least one surface of the metal.

14. A method of making an enclosed substrate, the method comprising:
(A) enclosing a polymeric material with an anodized metal,
wherein the polymeric material comprises a polymer composite, a carbon fiber composite, or mixtures thereof,
wherein the polymer composite comprises silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof,
wherein the carbon fiber composite comprises (i) carbon fibers, and (ii) silicone-based materials, polycarbonate, acrylonitrile butadiene styrene, polyetherimide, polysulfone, polyether ether ketone, polyphenylsulfone, polybutylene terephthalate (PBT), polyphenylene sulfide (PPS), polyamide (nylon), polyphthalamide (PPA), or mixtures thereof, and
wherein the anodized metal is selected from the group consisting of anodized aluminum, anodized aluminum alloy, anodized titanium, anodized titanium alloy, anodized zinc, anodized zinc alloy, anodized magnesium, anodized magnesium alloy, anodized niobium, anodized niobium alloy, anodized zirconium, anodized zirconium alloy, anodized hafnium, anodized hafnium alloy, anodized tantalum, anodized tantalum alloy, and combinations thereof; and
(B) adding the anodized metal enclosing the polymeric material to an electronic device.

15. The method of claim 14 further comprising:
(A-2) mechanically shaping the anodized metal enclosing the polymeric material.
